(19) United States
(12) Patent Application Publication
(10) Pub. No.: US 2025/0309018 A1
(43) Pub. Date: Oct. 2, 2025

(54) ENCAPSULATED SEMICONDUCTOR PACKAGES INCLUDING MULTIFUNCTIONAL INTERFACE MATERIAL (MIM) STRUCTURES

(71) Applicant: SanDisk Technologies, Inc., Milpitas, CA (US)

(72) Inventors: Yuanheng Zhang, Shanghai (CN); Simon Dong, Shanghai (CN); Yidong Zou, Shanghai (CN); Yonglong Liu, Shanghai (CN); Jerry Tang, Shanghai (CN); Fen Yu, Shanghai (CN); Derek Mong, Malaysia (MY)

(21) Appl. No.: 18/623,584

(22) Filed: Apr. 1, 2024

(51) Int. Cl. H01L 23/31; H01L 21/56; H01L 23/00; H01L 23/29; H01L 25/065; H10B 80/00

(52) U.S. Cl. CPC H01L 23/3135; H01L 21/566; H01L 23/295; H01L 24/32; H01L 24/48; H01L 24/73; H01L 25/0657; H10B 80/00; H01L 2224/32145; H01L 2224/32225; H01L 2224/48145; H01L 2224/48227; H01L 2224/48992; H01L 2224/73265; H01L 2225/06506; H01L 2225/0651; H01L 2924/1438

(57) ABSTRACT

A semiconductor package includes a multifunctional interface material (MIM) structure provided on a stack of memory dies. The MIM structure includes an adhesive layer disposed directly over a top surface of the top memory die of the stack of memory dies. The MIM structure also includes a polymer layer disposed directly over the adhesive layer. The adhesive layer of the MIM structure receives and secures a portion of the wires of the semiconductor package that contact the top memory die to minimize undesirable movement and disconnection of the wires from the top memory die. The polymer layer of the MIM structure compresses the adhesive layer to aid in securing the wires within the adhesive layer. The polymer layer also protects the adhesive layer within the semiconductor package during operation.

### BACKGROUND

Semiconductor packages, such as non-volatile memory devices, are used in various electronic devices such as cellular telephones, digital cameras, personal digital assistants, medical electronics, mobile computing devices, and the like. Because of its inclusion in most modern electronic devices, the demand for semiconductor packages is increasing. Additionally, as processing expectations increase and the size of electronic devices decrease, the desire for higher capacity, smaller size, and higher performance of these semiconductor packages increases with demand. However, it is increasingly difficult to reduce the size of the semiconductor package without sacrificing the capacity, stability, and/or reliability of the semiconductor package.

For example, in order to increase the capacity of a non-volatile memory device, additional memory dies are added to a stack of memory dies included with the non-volatile memory device. However, as additional memory dies are added to the stack, the thickness or height of the semiconductor package increases. Additionally, as additional memory dies are added to the stack, the risk of bond wires becoming crossed, overlapped, and/or inoperable also increases. For example, bond wires extending from and electrically connecting the top memory die to the substate often become disconnected from a contact formed on the memory die/substrate, rendering the bond wire inoperable. In other examples, these bond wires can be swept and/or sag within the semiconductor package, which reduces the reliability and performance of the bond wires, and in turn, the semiconductor package as a whole.

Bond wires are often positioned within an epoxy-resin that surrounds various parts of the semiconductor package. However, during the encapsulation with mold flow impact, the epoxy-resin does not provide stability for the bond wires, nor does the epoxy-resin positionally secure or affix the bond wires within the semiconductor packages. In some instances, when forming the semiconductor packages, it is the process of flowing the epoxy-resign over the bond wires that causes disconnection, wire short, sagging, and other negative effects on the bond wires.

Accordingly, it would be beneficial for a semiconductor package to securely fix the bond wires within the semiconductor package to prevent excessive movement and flexion of the bond wires during the semiconductor package creation process and during operation, without increasing the size or height of the semiconductor package.

### SUMMARY

The present disclosure generally relates to semiconductor packages, and more particularly, to encapsulated semiconductor packages including multifunctional interface material (MIM) structures disposed over a top die of the packages.

In an example, the encapsulated semiconductor package includes a MIM structure that secures wires within the package. For example, wires extending to and contacting the top die of a plurality of stacked dies for the semiconductor package extend through and are secured or embedded within a first layer of the MIM structure. The first layer of the MIM structure that secures the wires therein substantially prevents undesirable movement of the wires to help maintain a connection between the wire and the top die. Additionally in the example, by minimizing the movement of the wire using the MIM structure in the semiconductor package, undesirably operational effects, such as wire sweeping and wire sagging, are reduced or eliminated. That is, where the wires are desirably secured and positionally affixed within the MIM structure, the wires cannot excessively move within the semiconductor package, and thus the risk of sweeping or sagging is reduced, and the reliability of the package increases. In one example, the first layer in which the wires extend through is a curable, adhesive layer that establishes a strong bond between the MIM structure and the top die, as well as ensures the securing of the wires within the first layer during operation. Furthermore, by securing the wires within the MIM structure and preventing undesirable movement, the loop height of the wires can be reduced, which in turn allows for semiconductor package to have a decreased overall height or thickness.

Additionally, the MIM structure can also include a second layer formed above the first layer receiving and securing the wires therein. In an example, the second layer can provide more rigidity to the MIM structure and also protect the first layer receiving the wires. The second layer can also provide a compressive force on the first layer receiving the wires to further support the securing and affixing of the wires within the MIM structure. In another example, second layer can include a reduced height as well. Inclusion of the MIM structure increases the stability and reliability of the semiconductor package, while also decreasing the overall size or thickness of the semiconductor package.

Accordingly, examples of the disclosure provide a semiconductor package that includes a substrate and a plurality of stacked dies disposed over the substrate. In an example, the plurality of stacked dies include a top die positioned above the substrate. The top die includes a top surface and a die contact. A multifunctional interface material (MIM) structure is disposed over the top die and includes an adhesive layer disposed directly over the top surface of the top die and a polymer layer disposed directly over the adhesive layer. The semiconductor package also includes a wire contacting the die contact. In an example, at least a portion of the wire extends through the adhesive layer of the MIM structure.

Additional examples of the disclosure provide a method for creating a semiconductor package. In an example, the method includes disposing a plurality of stacked dies over a substrate. In an example, the plurality of stacked dies includes a top die positioned above the substrate. The top die has a top surface and a die contact formed on the top surface. A portion of a wire is connected to the die contact of the top die. A multifunctional interface material (MIM) structure is disposed directly over the top die of the plurality of stacked dies. In an example, the MIM structure surrounds the first portion of the wire connected to the die contact of the top die. Additionally a molding compound is provided over the substrate and at least a portion of the plurality of stacked dies.

Further examples of the disclosure provide a semiconductor package that includes a substrate having a first contact means. A plurality of stacked dies are disposed over the substrate. In an example, a top die of the plurality of stacked dies includes a top surface and a second contact means. A connection means extends between and electrically connects the second contact means of the top die and the first contact means of the substrate. A securing means is disposed directly over the top die and receives and secures a portion of the connection means. The semiconductor package also includes a protective means disposed directly over the securing means.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a perspective view of an encapsulated semiconductor package including a multifunctional interface material (MIM) structure, according to an example.

FIG. 2 shows a front cross-sectional view of the encapsulated semiconductor package of FIG. 1 taken along line 2-2, according to the example.

FIG. 3 shows a front cross-sectional view of the encapsulated semiconductor package of FIG. 1 taken along line 3-3, according to the example.

FIGS. 4-6 show front cross-sectional views of the encapsulated semiconductor package including a MIM structure having additives formed therein, according to various examples.

FIG. 7 shows a front cross-sectional view of the encapsulated semiconductor package including a MIM structure, according to another example.

FIG. 8 shows a front cross-sectional view of the encapsulated semiconductor package including a MIM structure, according to an additional example.

FIG. 9 shows a flowchart illustrating processes for creating encapsulated semiconductor packages including a MIM structure, according to an example.

FIGS. 10-15 show front cross-sectional views of an encapsulated semiconductor package undergoing processes for creation similar to those shown in FIG. 9, according to an example.

FIG. 16 shows a front cross-sectional view of the encapsulated semiconductor package including a MIM structure, according to another example.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As an initial matter, in order to clearly describe the current disclosure, it will become necessary to select certain terminology when referring to and describing relevant components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

As discussed herein, the disclosure relates generally to semiconductor packages, and more particularly, to encapsulated semiconductor packages including multifunctional interface material (MIM) structures disposed over a top die of the packages. In an example, the MIM structure provides an adhesive layer that receives a portion of the bond wires included in the semiconductor packages. That is, portions of the bond wires of the semiconductor package extend through and are secured or embedded within the adhesive layer of the MIM structure. The adhesive layer prevents undesirable, excessive movement of the wires within the semiconductor package during operation. In the example, the MIM structure also provides a polymer layer formed over the adhesive layer. The polymer layer provides a compressive force on the adhesive layer to ensure the wires remain secured within the adhesive layer, while also providing protection to the adhesive layer itself. Collectively, the adhesive layer and the polymer layer forming the MIM structure can include a predetermined height or thickness that is smaller than conventional materials disposed over top dies for conventional semiconductor packages.

Accordingly, many technical benefits may be realized including, but not limited to, increasing the stability and reliability of a connection between bond wires and die contacts formed in the top die of semiconductor packages. Specifically, the inclusion of the MIM structure and the securing of the wires in the adhesive layer of the MIM structure reduces undesirable and excessive movement of the wires during operation, which reduces the risk of disconnection, wire sweeping, and wire sagging within the semiconductor package. Additional benefits include, but are not limited to, the polymer layer providing a compressive force on the adhesive layer to aid in the securing and affixing of the wires within the adhesive layer, while also providing protection to the adhesive layer itself. Furthermore, the benefits of utilizing MIM structure include, but are not limited to, reducing the loop height of the wires extending through the adhesive layer, and ultimately reducing the overall height or thickness of the semiconductor package itself.

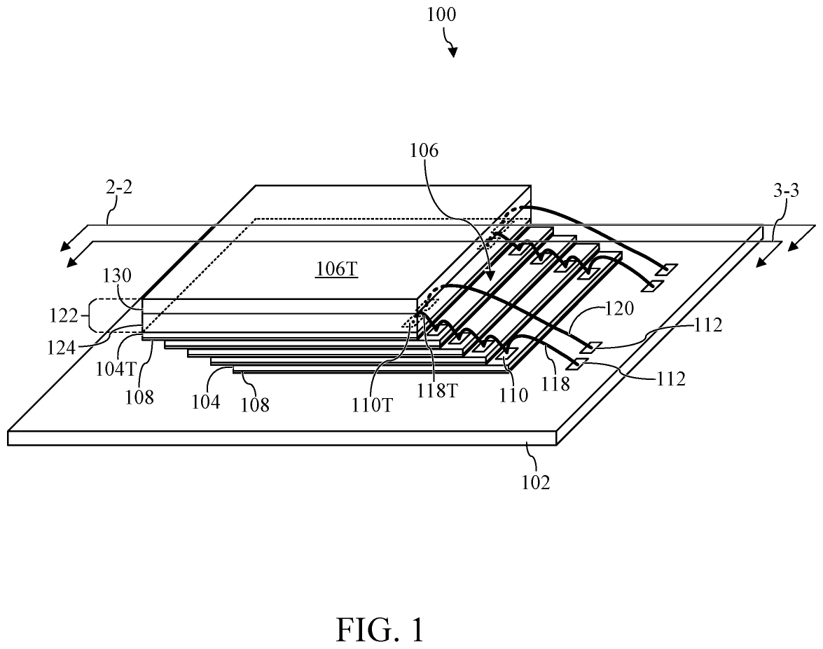

These and other examples are discussed below with reference to FIGS. 1-16. However, those skilled in the art will readily appreciate that the detailed description given herein with respect to these Figures is for explanatory purposes only and should not be construed as limiting.

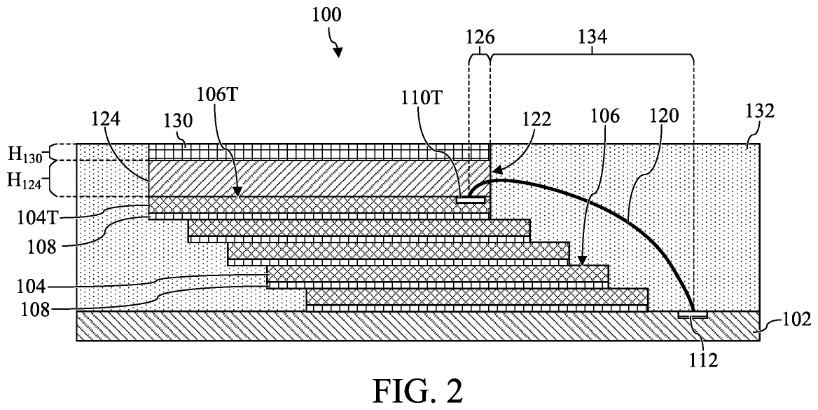

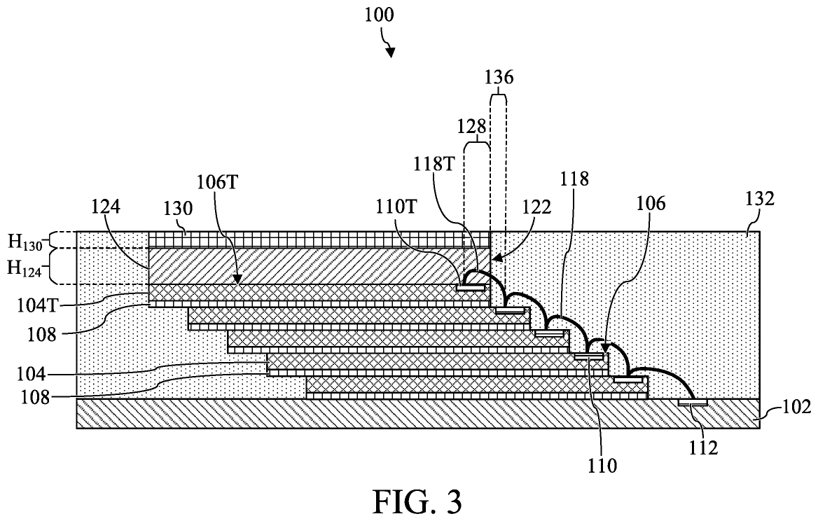

Turning to FIGS. 1-3, an encapsulated semiconductor package 100 (hereafter, “semiconductor package 100”) is shown in various views. More specifically, FIG. 1 shows a perspective view of semiconductor package 100, FIG. 2 shows a cross-sectional front view of semiconductor package 100 taken along line 2-2 in FIG. 1, and FIG. 3 shows a cross-sectional front view of semiconductor package 100 taken along line 3-3 in FIG. 1. Semiconductor package 100 shown in FIG. 1 has omitted the inclusion of a molding compound (see, FIGS. 2 and 3) for ease of view of the other components or structures of semiconductor package 100. As discussed herein, semiconductor package 100 includes a molding compound that substantially surrounds and/or is disposed over some of the various components or structures of the package.

In the non-limiting example, semiconductor package 100 includes a substrate 102. Substrate 102 forms the base layer for semiconductor package 100. Substrate 102 is formed as a semiconducting material and/or is formed from as any suitable material or material composition that includes semiconducting properties/characteristics. For example, substrate 102 is formed from indium phosphide (InP) or Indium gallium arsenide (InGaAs). In other non-limiting examples, substrate 102 is formed from, without limitation, substances consisting essentially of one or more compound semiconductors. Substrate 102 can also be formed as a bulk substrate or as part of a silicon-on-insulator (SOI) wafer. Additionally, or alternatively, substrate 102 is formed from, for example, silicon (Si), silicon carbide (SiC), germanium (Ge), germanium oxide (GeO), cadmium zinc telluride (CdZnTe), or gallium arsenide (GaAs). Furthermore, substrate 102 is fabricated as a layer of semiconductor material, substances or materials consisting essentially of one or more compound semiconductors having a composition defined by the formula AlX1GaX2JnX3AsY1PY2NY3SbY4, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substances can include II-VI compound semiconductors having a composition ZnA1CdA2SeB1TeB2, where A1, A2, B1, and B2 are relative proportions each greater than or equal to zero and A1+A2+B1+B2=1 (1 being a total mole quantity).

Semiconductor package 100 also includes a plurality of stacked dies 104, 104T. As shown in FIGS. 1-3, the plurality of stacked dies 104, 104T are disposed over, positioned on, and/or formed above substrate 102. In the non-limiting example, the plurality of stacked dies 104, 104T are staggered or stepped with respect to one another when disposed over substrate 102. As such, at least a portion of a top surface 106 for each die of the plurality of stacked dies 104 is uncovered by the adjacent die positioned thereon. As discussed herein, additional materials and/or structures cover the uncovered top surfaces 106 of the plurality of stacked dies 104 in semiconductor package 100 (e.g., molding compound). Additionally, and as shown, the plurality of stacked dies 104, 104T includes a top die 104T positioned opposite and/or above the substrate, and is formed over all remaining die of the plurality of stacked dies 104. Top die 104T of the plurality of stacked dies 104, 104T includes a top surface 106T that receives, directly contacts, and/or is substantially covered by a multifunctional interface material (MIM) structure of semiconductor package 100, as discussed herein.

In a non-limiting example, the plurality of stacked dies 104, 104T of semiconductor package 100 are formed as NAND memory dies. However, it is understood that the plurality of stacked dies 104, 104T can be formed as any volatile or non-volatile memory die, or any other suitable circuit stack-up configuration. Additionally in the non-limiting example shown in FIGS. 1-3, the plurality of stacked dies 104, 104T includes five (5) dies. It is understood that the number of dies included in the plurality of stacked dies 104 is illustrative, and semiconductor package 100 can include any suitable number of dies to form the stacked dies 104, 104T. Furthermore, although only a single plurality of stacked dies 104, 104T are shown in FIGS. 1-3, it is understood that semiconductor package 100 can include more than one plurality of stacked dies, where each of the plurality of stacked dies is disposed or formed over substrate 102, adjacent to one another.

As shown in FIGS. 1-3, semiconductor package 100 also includes a plurality of die attach films (DAF) 108 (hereafter, “DAF 108”). Each of the plurality of DAF 108 is disposed between each of the plurality of stacked dies 104, 104T and/or between die 104 and substrate 102. More specifically, DAF 108 are disposed over and/or substantially cover a bottom surface of each of the plurality of stacked dies 104, 104T, opposite top surface 106, 106T, to bond or connect dies 104, 104T to adjacent dies 104 and/or substrate 102. In a non-limiting example, DAF 108 coupled to top die 104T directly contacts top surface 106 of an adjacent die 104 to bond and/or connect top die 104T to the adjacent die 104. Additionally, die 104 positioned adjacent substrate 102 is coupled and/or connected directly to substrate via DAF 108. DAF 108 is formed as any suitable adhesive material capable of withstanding the operational parameters, characteristics, and/or constraints (e.g., temperature change) of semiconductor package 100.

Each of the plurality of stacked dies 104, 104T includes at least one die pad, connection pad, or die contact 110, 110T (hereafter, “die contacts 110, 110T”). As shown in FIG. 1, each die 104, 104T includes a die contact 110, 110T formed in die 104, 104T and/or on the uncovered (portion) of top surface 106, 106T. For example, top die 104T includes a plurality of die contacts 110T (shown in phantom in FIG. 1) formed directly in top die 104T and/or directly on top surface 106T of top die 104T. Each distinct die of the plurality of dies 104 formed below and/or between top die 104T and substrate 102 also includes a plurality of die contacts 110. As shown in the non-limiting example, die contacts 110 are formed directly in respective dies 104 and/or directly on the uncovered top surfaces 106 for each die of the plurality of dies 104. As discussed herein, the plurality of die contacts 110, 110T are used to electrically couple each of the distinct dies 104, 104T to one another, and/or to electrically couple the die(s) 104, 104T to substrate 102, via substrate contact 112 formed directly in and/or directly on substrate 102. Die contacts 110, 110T formed in the plurality of dies 104, 104T are of a predetermined configuration and/or circuitry based on operational and/or structural parameters of semiconductor package 100. It is understood that the number of die contacts 110, 110T and/or the configuration of die contacts 110, 110T of semiconductor package 100 shown in FIGS. 1-3 is illustrative. As such, other non-limiting examples of semiconductor package 100 can include more or less die contacts 110, 110T and/or can include distinct configurations or circuitry than the non-limiting example shown in FIG. 1.

Semiconductor package 100 also includes a plurality of wires 118, 120 (shown partially in phantom in FIG. 1) for electrically connecting various components therein. More specifically, semiconductor package 100 includes wires 118 extending between, contacting, electrically connecting, and/or communicatively coupling the plurality of dies 104, 104T to one another, and/or to substrate 102. As shown in the non-limiting example of FIGS. 1 and 3, each wire 118 extends between and/or directly contact die contacts 110, 110T for two adjacent stacked dies 104, 104T. For example, wire 118T extends between, contacts, and/or electrically connects die contact 110T of top die 104T to the die contact 110 of the adjacent die 104. Additionally, one wire of the plurality of wires 118 extends between and/or directly contacts substrate contact 112 and die contact 110 for the immediately adjacent die of the plurality of stacked dies 104. In the non-limiting example, wires 118 electrically connect, communicatively couple, and/or form a transmission path between each of the plurality of stacked dies 104, 104T and substrate 102.

Additionally, wires 120 extend between, contact, electrically connect, and/or communicatively couple top die 104T directly to substrate 102. As shown in FIGS. 1 and 2, each wire 120 extends between and/or directly contacts die contact 110T for top die 104T and substrate contact 112 of substrate 102. In the non-limiting example, wires 120 electrically connect, communicatively couple, and/or form a transmission path between top die 104T of the plurality of stacked dies 104, 104T and substrate 102.

Wires 118, 120 are formed from any suitable material that includes conductive and/or electrical properties to form an electrical transmission path between different components of semiconductor package 100. For example, wires 118, 120 are formed from gold (Au) wire. Additionally, the non-limiting example of semiconductor package 100 shown in FIG. 1 includes ten (10) wires 118, and two (2) wires 120. It is understood that the number of wires 118, 120 included in semiconductor package 100 is dependent, at least in part on, the number of dies in the plurality of stacked dies 104, 104T, the number of distinct plurality of stacked dies 104, 104T, the number of die contacts 110, 110T, the number of substrate contacts 112, and/or the configuration/circuitry of the plurality of stacked dies 104, 104T for semiconductor package 100.

A multifunctional interface material (MIM) structure 122 (hereafter, “MIM structure 122”) is disposed over the plurality of stacked dies 104, 104T. More specifically, and as shown in FIGS. 1-3, semiconductor package 100 includes MIM structure 122 disposed directly over and/or substantially covering top surface 106T of top die 104T. As such, no portion of top surface 106T of top die 104T is exposed and/or uncovered by MIM structure 122 in semiconductor package 100.

In the non-limiting example, MIM structure 122 includes an adhesive layer 124. Adhesive layer 124 is disposed directly over, contacts, is coupled to, and/or adheres directly to top surface 106T of top die 104T. Adhesive layer 124 is also disposed directly over, and/or is adhered to die contacts 110T formed on top surface 106T of top die 104T. At least a portion of wires 118, 120 also extend through adhesive layer 124 of MIM structure 122. More specifically, and as shown in FIG. 2, wire 120 includes a first portion 126 extending through and substantially surrounded by adhesive layer 124 of MIM structure 122 to contact die contact 110T. Additionally, and as shown in FIG. 3, wire 118T includes a first portion 128 extending through and substantially surrounded by adhesive layer 124 of MIM structure 122 to contact (a distinct) die contact 110T of top die 104T. Adhesive layer 124 of MIM structure 122 also includes and/or is formed with a predetermined height (H₁₂₄) between approximately 20 micrometers (μm) and approximately 30 μm. Additionally, adhesive layer 124 is formed from any suitable material that surrounds, encompasses, and/or envelops first portions 126, 128 of wires 120, 118T, and secures, affixes, and/or embeds first portions 126, 128 within adhesive layer 124 of MIM structure 122 during operation of semiconductor package 100. In a non-limiting example, adhesive layer 124 of MIM structure 122 includes methyl acrylate, ethyl acrylate, n-butyl acrylate and methyl methacrylate, n-butyl methacrylate, amino resin, acrylic resin, epoxy resin, phenol resin, polyurethane, their derivative polymers, or any other similar material.

MIM structure 122 also includes a polymer layer 130. Polymer layer 130 is disposed directly over adhesive layer 124. More specifically, and as shown in FIGS. 1-3, polymer layer is formed, disposed over, and/or substantially covers adhesive layer 124, such that adhesive layer 124 is positioned between polymer layer 130 and top surface 106T of top die 104T for the plurality of stacked dies 104, 104T formed in semiconductor package 100. In the non-limiting example, and as discussed herein, polymer layer 130 of MIM structure 122 is exposed and/or forms a portion of the top layer for semiconductor package 100. Polymer layer 130 of MIM structure 122 includes and/or is formed with a predetermined height (H₁₃₀) between approximately 10 micrometers (μm) and approximately 20 μm. As such, an overall height (H₁₂₄+H₁₃₀) of MIM structure 122 is between approximately 30 μm and approximately 50 μm. Additionally, polymer layer 130 is formed from any suitable material that disposed over to protect and/or provide stability to adhesive layer 124 of MIM structure 122. In a non-limiting example, polymer layer 130 of MIM structure 122 can be composed of phenolic resins, urea-formaldehyde resins, melamine resins, unsaturated polyester resins, epoxy resins, silicone resins, polyurethanes and their derivatives, a mixture of the above materials, or any other similar material.

Turning to FIGS. 2 and 3, semiconductor package 100 also includes a molding compound 132. Molding compound 132 is disposed over various portions and/or components of semiconductor package 100. More specifically, molding compound 132 is disposed over exposed portions of substrate 102, substrate contacts 112, and at least a portion of the plurality of stacked dies 104. As shown in the non-limiting example, molding compound 132 is disposed directly over exposed surfaces 106 of the plurality of stacked dies 104 positioned between top die 104T and substrate 102, die contacts 110 formed in the exposed surfaces 106, and the sidewalls of the plurality of stacked dies 104, 104T. Additionally, molding compound 132 is also formed adjacent to top surface 106T of top die 104T and MIM structure 122. That is, in the example, molding compound 132 is formed directly adjacent to, but does not cover, top surface 106T of top die 104T, as well as adhesive layer 124 and polymer layer 130 forming MIM structure 122. As shown in FIGS. 2 and 3, molding compound 132 and polymer layer 130 of MIM structure 122 are substantially planar and/or in planar alignment to collectively form the top surface of semiconductor package 100.

Molding compound 132 is also formed over at least distinct portions of wires 118, 118T, 120. Turning to FIG. 2, molding compound 132 is formed over a second portion 134 of wire 120. More specifically, wire 120 includes second portion 134, formed adjacent first portion 126, that is disposed within and/or extends through molding compound 132. As such, second portion 134 of wire 120, extending between first portion 126 and substate contact 112, is substantially surrounded by and/or embedded within molding compound 132. As shown in FIG. 3, wires 118 extending between substrate contact 112 and die contacts 110, as well as wires 118 extending between distinct die contacts 110 formed in stacked dies 104, are also disposed within, embedded in, and/or extend through molding compound 132, such that molding compound 132 substantially surrounds wires 118. Additionally, wire 118T extending between die contact 110T formed on top die 104T and the adjacent stacked die 104 includes a second portion 136, formed adjacent first portion 128. Molding compound 132 is formed over second portion 136 of wire 118T. More specifically, wire 118T includes second portion 136 that is disposed within and/or extends through molding compound 132. In the non-limiting example, second portion 134 of wire 118T is substantially surrounded by and/or embedded within molding compound 132. Molding compound 132 is formed from any suitable material that can be flowed over the respective portions of semiconductor package 100 to surround those portions, as discussed herein. In a non-limiting example, molding compound 132 is formed from an epoxy-based resin, using phenolic resins, polyester resins, polyamide resins, etc. as the main body, combined with epoxy resins such as o-cresol aldehyde epoxy resin, bromine-containing epoxy resin, biphenyl-type epoxy resin, dicyclopentadienyl-type epoxy resin and other epoxy resins. In other examples, molding compound 132 can also be combined with linear phenolic resins, curing agents such as anhydrides and polyamines, curing accelerators such as amines, imidazoles and phosphines, flame retardants such as antimony compounds and bromides, mold releasing agents, fillers and coloring agents.

The inclusion of MIM structure 122 provides added benefits to semiconductor package 100. For example, and as discussed herein, adhesive layer 124 of MIM structure 122 securely holds and/or affixes first portion 126, 128 of wires 120, 118T therein and substantially prevents movement of wires 118T, 120 after formation of semiconductor package 100. As a result, the risk of wire sweeping and/or wire sagging is minimized or eliminated. Additionally, securing and/or affixing first portion 126, 128 of wires 120, 118T within adhesive layer 124 of MIM structure also prevents and/or reduces the occurrence of wire shorts, ball lifts, and/or the disconnecting of wires 118T, 120 from die contacts 110T formed in top surface 106T of top die 104T. Furthermore, extending wires 118T, 120 through, and/or securing wires 118T, 120 within adhesive layer 124 also reduces the loop height of wires 118T, 120 without reducing the desired spacing for wires 118T, 120 within semiconductor package 110. The reduction in the loop height of wires 118T, 120 allows for the overall height or thickness of semiconductor package 100 to be reduced as well. The use of polymer layer 130 in MIM structure 122 provides additional protection and/or stability to adhesive layer 124, which in turn minimizes the undesirable problems (e.g., wire sweeping, wire sagging, etc.) associated with wires 118T, 120 when MIM structure 122 is not implemented in semiconductor package 100. The improved stability and/or reliability of semiconductor package 100 including MIM structure 122 further improves operational performance and operational longevity of semiconductor package as well.

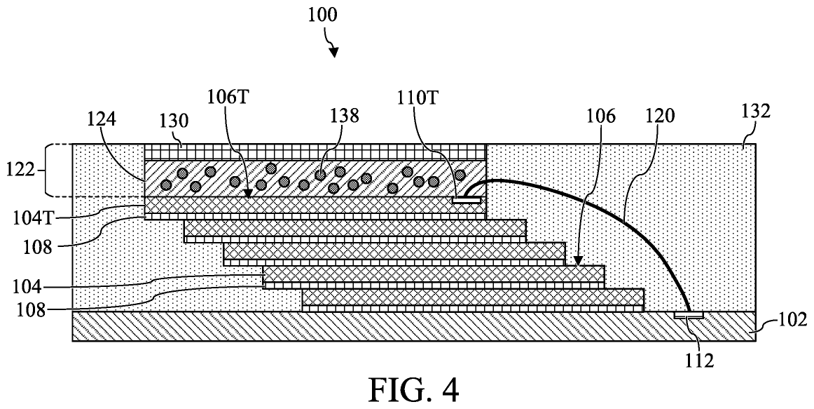

FIGS. 4-6 show cross-sectional front views of additional examples of semiconductor package 100. It is understood that similarly numbered and/or named components may function in a substantially similar fashion. Redundant explanation of these components has been omitted for clarity and/or brevity.

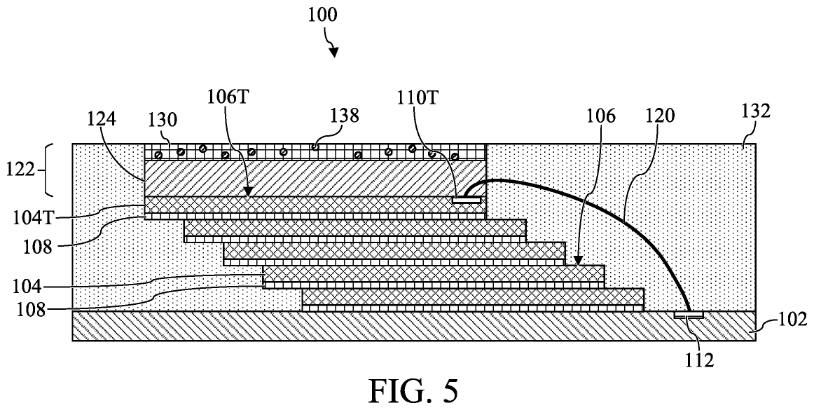

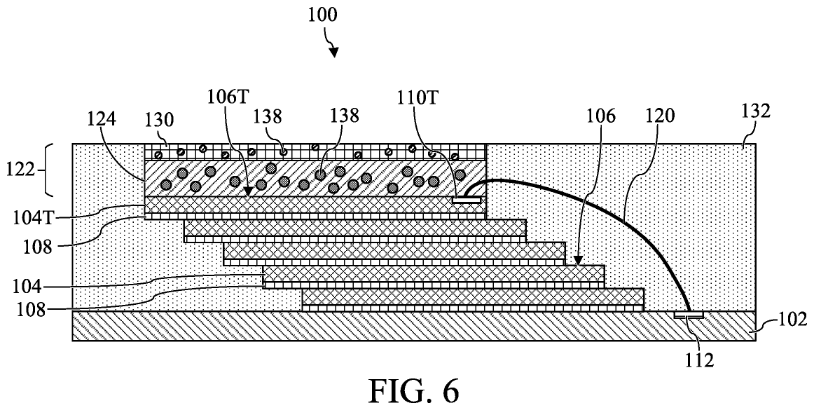

In the non-limiting examples shown in FIGS. 4-6, MIM structure 122 includes an additive 138. More specifically, additive 138 is disposed within, formed integral with, and/or compositionally added to adhesive layer 124 and/or polymer layer 130 of MIM structure 122. As shown in FIG. 4, additive 138 is disposed only within adhesive layer 124, and in FIG. 5, additive 138 is disposed only within polymer layer 130. In the example shown in FIG. 6 additive 138 is disposed within both adhesive layer 124 and polymer layer 130 of MIM structure 122. Additive 138 is included in MIM structure 122 to adjust the (operational) characteristics of the adhesive layer 124 and/or polymer layer 130 for semiconductor package 100. For example, additive 138 can be formed from a predetermined material to adjust, alter, and/or change the thermal conductivity of MIM structure 122. In other non-limiting examples, additive 138 can be formed from predetermined material(s) that adjust, alter, and/or change characteristics of MIM structure 122 including, but not limited to, flame retardancy, electrical properties, abrasion resistance, bending/flexion properties, fatigue resistance, and the like. Additive 138 disposed within adhesive layer 124 and/or polymer layer 130 can be formed from aluminum oxide, magnesium oxide, aluminum nitride, boron nitride, diamond powder, or any other suitable material that can adjust operational characteristics of MIM structure 138. It is understood that where adhesive layer 124 and polymer layer 130 both include additive 138 (see, FIG. 6), additive 138 included within adhesive layer 124 can compositionally defer from additive 138 included within polymer layer 130. Additionally, it is understood that more than one additive 138 can be included within a single layer of MIM structure 122. For example, polymer layer 130 can include two distinct additives 138, where each of the two distinct additives adjust different characteristics of polymer layer 130 as desired.

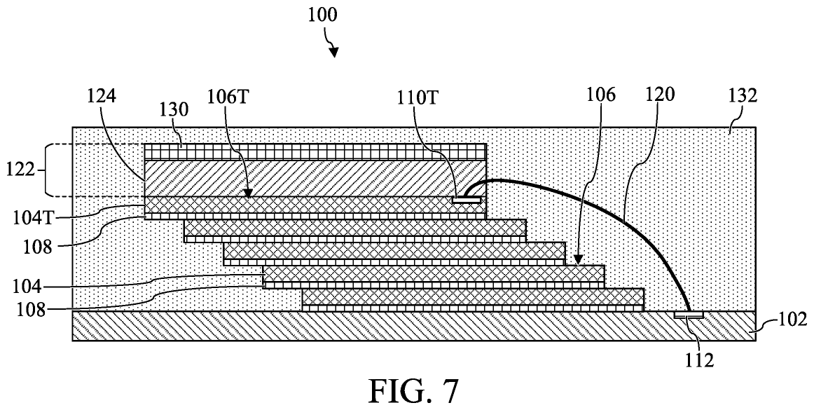

FIG. 7 shows a cross-sectional front view of another example of semiconductor package 100. Distinct from semiconductor package 100 shown and discussed herein with respect to FIGS. 1-3, semiconductor package 100 shown in FIG. 7 includes molding compound 132 disposed over MIM structure 122. More specifically, molding compound 132 is disposed directly over, covers, and/or substantially surrounds polymer layer 130 of MIM structure 122. In the non-limiting example, first portions 126, 128 of wires 120, 118T extend through and/or are secured within adhesive layer 124 of MIM structure 122. However, polymer layer 130 does not form a top surface of semiconductor package 100, as previously discussed herein (see, FIGS. 1-3). Rather, in the non-limiting example shown in FIG. 7, molding compound 132 defines the entire top surface of semiconductor package 100, and MIM structure is formed below at least a portion of molding compound 132.

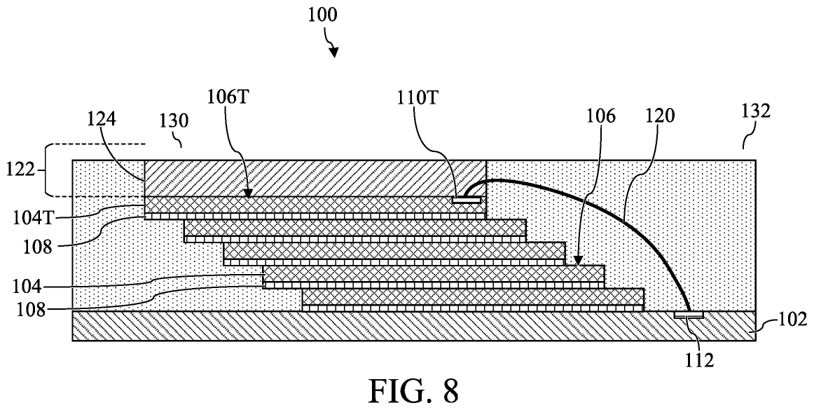

FIG. 8 shows a cross-sectional front view of an additional example of semiconductor package 100. In the non-limiting example, MIM structure 122 only includes adhesive layer 124. More specifically, and distinct from semiconductor packages discussed herein (see, FIGS. 1-7), MIM structure 122 of semiconductor package 100 shown in FIG. 8 only includes adhesive layer 124 disposed directly over top surface 106T of top die 104T for the plurality of stacked dies 104, 104T. In the example, first portions 126, 128 of wires 120, 118T extend through and/or are secured within adhesive layer 124 of MIM structure 122. Additionally as shown, adhesive layer 124 of MIM structure 122 is exposed and/or forms a portion of the top layer for semiconductor package 100—along with molding compound 132.

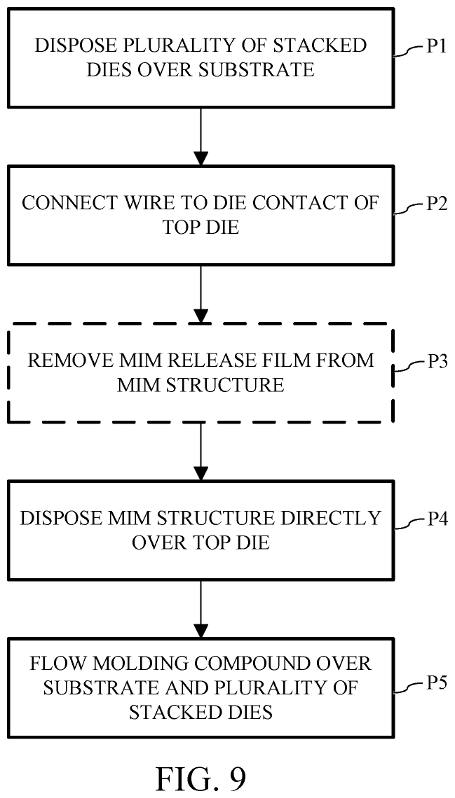

FIG. 9 shows example processes for creating a semiconductor package. Specifically, FIG. 9 is a flowchart depicting one example process for creating an encapsulated semiconductor package including multifunctional interface material (MIM) structures. In some cases, the processes can form the various non-limiting examples of semiconductor package 100, as discussed above with respect to FIGS. 1-8.

In process P1, a plurality of stacked dies are disposed over a substrate. More specifically, the plurality of stacked dies are disposed over, position on, and/or formed above the substrate in a staggered and/or stepped arrangement. As such, at least a portion of a top surface for each stacked die is uncovered by adjacent dies. Additionally, a top die of the plurality of stacked dies, positioned above the substrate, includes a top surface that is completely uncovered and/or exposed. Each die of the plurality of stacked dies, including the top die, includes at least one die contact formed directly in and/or directly on the exposed (portion of the) top surface. Substrate also includes at least one substrate contact formed therein and/or thereon. Die contact(s) and substrate contact(s) are formed in a predetermined configuration, dependent on semiconductor package's device type (e.g., NAND memory device).

In process P2, a wire is connected to the die contact formed in/on top die of the plurality of stacked dies. More specifically, a wire is connected, contacted, and/or electrically/communicatively coupled to the die contact formed in/on the top surface of the top die, and extends away from the top surface of top die. In a non-limiting example, the wire connected to the die contact of top die includes a first portion directly connected to and positioned substantially adjacent the die contact. Depending on the configuration of the die contacts and substrate contacts, the wire connected to the die contact of top die in process P2 can extend toward an adjacent die contact formed in and/or on an adjacent die of the plurality of stacked dies, or alternatively can extend toward a substrate contact formed in and/or on the substrate.

In process P3 (shown in phantom as optional), a release film is removed from a multifunctional interface material (MIM) structure. That is, a MIM structure that subsequently disposed over the plurality of stacked dies (see, process P4) includes a MIM release film. The MIM release film is coupled to, disposed over, and/or substantially covers the adhesive layer of the MIM structure. In process P3, the MIM release film is removed to expose the adhesive layer of the MIM structure for subsequent processing. The MIM release film is coupled to the adhesive layer to protect the adhesive layer and/or to aid in the transportation and positioning of the MIM structure during formation of the semiconductor package, as discussed herein.

In process P4, the MIM structure is disposed over the top die of the plurality of stacked dies. More specifically, the MIM structure is disposed directly over and/or substantially covering the top surface of the top die. As such, no portion of the top surface of top die is exposed and/or uncovered by the MIM structure in the semiconductor package. Additionally, the MIM structure is disposed directly over and/or substantially covers each die contact formed in the top surface of the top die. When disposed directly over the top die, the MIM structure substantially surrounds the first portion of the wire connected to the die contact formed in the top surface of the top die. As discussed herein, the MIM structure includes an adhesive layer and a polymer layer. As such, the disposing of the MIM structure in process P4 also includes disposing the adhesive layer of the MIM structure directly over the top surface of the top die, where the first portion of the wire extends through and/or is substantially surrounded by the adhesives layer. The disposing of process P4 further includes positioning or forming the polymer layer of the MIM structure adjacent the top surface of the top die. In the example, and as discussed herein, the polymer layer of the MIM structure is disposed directly over the adhesive layer, such that the adhesive layer is positioned between the top die of the plurality of stacked dies and the polymer layer. Furthermore, disposing the MIM structure/adhesive layer over the top die can also include curing the adhesive layer of the MIM structure. Curing the adhesive layer of the MIM structure substantially hardens or firms the adhesive layer and secures, affixes, and/or embeds the first portion of the wire within the adhesive layer. The time, temperature, and/or pressure for curing the adhesive layer of the MIM structure is dependent, at least in part, on a height/size of the adhesive layer in the MIM structure and/or the compositional make-up of the adhesive layer.

In process P5, a molding compound is flowed over the substrate and at least a portion of the plurality of stacked dies. More specifically, the molding compound is flowed, formed, and/or positioned over exposed portions of the substrate not covered by the plurality of stacked dies, as well as the exposed portions of each die of the plurality of stacked dies. The molding compound is also flowed over and/or substantially surrounds the substrate contacts, and the die contacts (excluding those formed in the top surface of the top die) formed in the stacked dies. Flowing the molding compound also includes surrounding a second portion of the wire with the molding compound. The second portion of the wire is formed adjacent the first portion, and extends through, is substantially surrounded by, and/or is embedded within the molding compound in process P5. In the example where the wire extends from the top die to the substrate contact, the second portion of the wire directly contacts and/or is electrically connected to the substrate contact formed in/on the substrate. Alternatively where the wire extends from the top die to a directly adjacent die, the second portion of the wire directly contacts and/or is electrically connected to the die contact formed in/on the exposed portion of the top surface of the adjacent die.

In a non-limiting example, flowing the molding compound in process P5 also includes forming the molding compound directly adjacent to the top surface of the top die, the adhesive layer of the MIM structure, and the polymer layer of the MIM structure. In this example, the molding compound does not cover or contact the top surface of the top die, but rather surrounds the top die, and the MIM structure, respectively. As such, the polymer layer of the MIM structure and the molding compound are in planar alignment and collectively form a top or upper surface of the semiconductor package. In another non-limiting example, flowing the molding compound in process P5 can include forming the molding compound over the MIM structure. More specifically in the example, the molding compound can be flowed, formed, and/or positioned adjacent to top die and the MIM structure, as well as be flowed, formed, and/or positioned directly over the polymer layer of the MIM structure. When formed over the MIM structure, the flowed molding compound can form the upper surface of the semiconductor package.

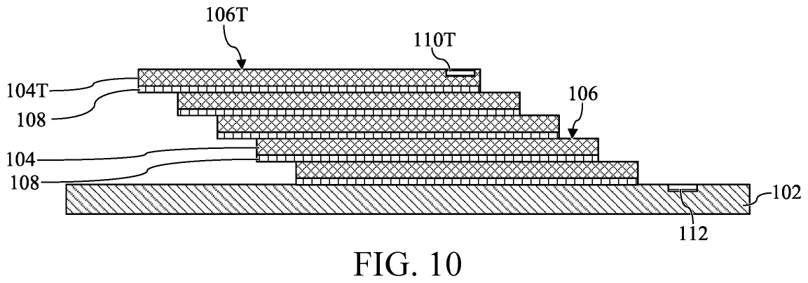

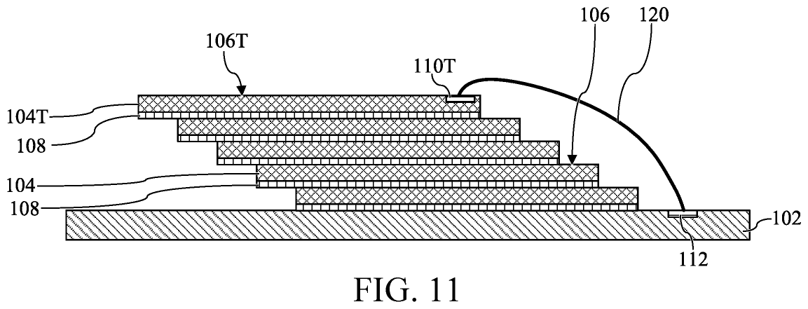

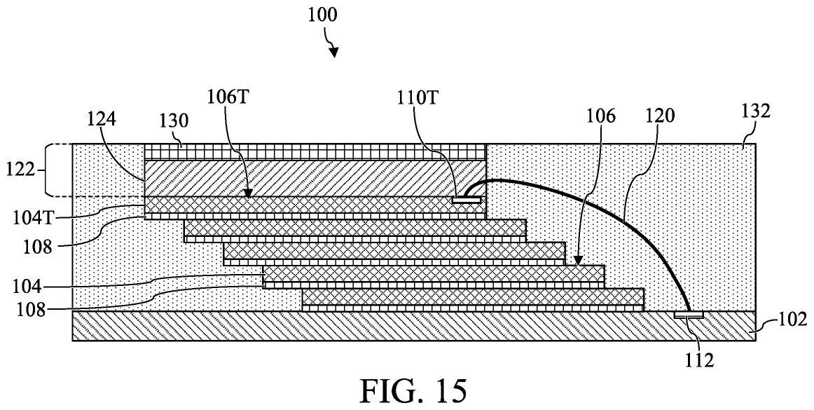

FIGS. 10-15 show various processes for creating semiconductor package 100 (see, FIG. 15). More specifically, FIGS. 10-15 show cross-sectional front views of semiconductor components or parts undergoing processes P1-P5 for creating encapsulated semiconductor package 100 including MIM structures 122, as shown and discussed herein with respect to FIG. 9. The non-limiting example shown in FIGS. 10-15 depicts a section of semiconductor package 100 that includes wire 120 (see e.g., FIG. 11) extending from top surface 106T of top die 104T to substrate contact 112 of substrate 102. It is understood that other sections of semiconductor package 100 (e.g., sections including wires 118, 118T) undergo similar processes of creation, as discussed herein. Additionally, it is understood that similarly numbered and/or named components may function in a substantially similar fashion. Redundant explanation of these components has been omitted for clarity and/or brevity.

FIG. 10 shows a cross-sectional front view of the plurality of stacked dies 104, 104T being disposed over substrate 102. More specifically, the plurality of stacked dies 104, 104T are disposed over, position on, and/or formed above substrate 102 in a staggered and/or stepped arrangement. As shown, at least a portion of top surface 106, 106T for each stacked die 104, 104T is uncovered by adjacent dies. Additionally, top die 104T of the plurality of stacked dies 104, 104T, positioned above substrate 102, includes top surface 106T that is completely uncovered and/or exposed in FIG. 10. As discussed herein, each die of the plurality of stacked dies 104, 104T, including top die 104T, includes at least one die contact 110 (not shown), 110T formed directly in and/or directly on the exposed (portion of the) top surface 106, 106T. Substrate 102 also includes substrate contacts 112 formed therein and/or thereon. FIG. 10 corresponds to process P1 shown in FIG. 9.

FIG. 11 shows wire 120 connected to die contact 110T formed in/on top die 104T of the plurality of stacked dies 104, 104T. More specifically, wire 120 is connected, contacts, and/or electrically/communicatively coupled to die contact 110T formed in/on top surface 106T of top die 104T and extends away from top surface 106T of top die 104T. In the non-limiting example shown, wire 120 connected to die contact 110T of top die 104T includes a first portion 126 directly connected to and positioned substantially adjacent die contact 110T, and second portion 134 formed adjacent first portion 126. Wire 120 extends toward substrate 102, and second portion 134 of wire 120 is connected, contacts, and/or electrically coupled to substrate contact 112 formed in and/or on substrate 102. FIG. 11 corresponds to process P2 shown in FIG. 9.

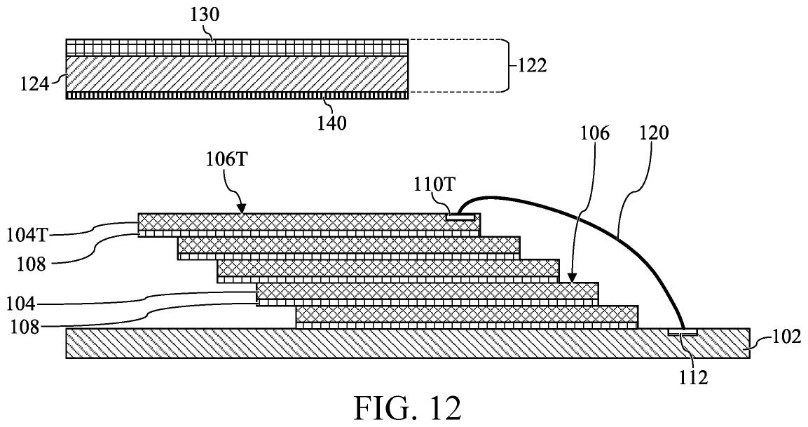

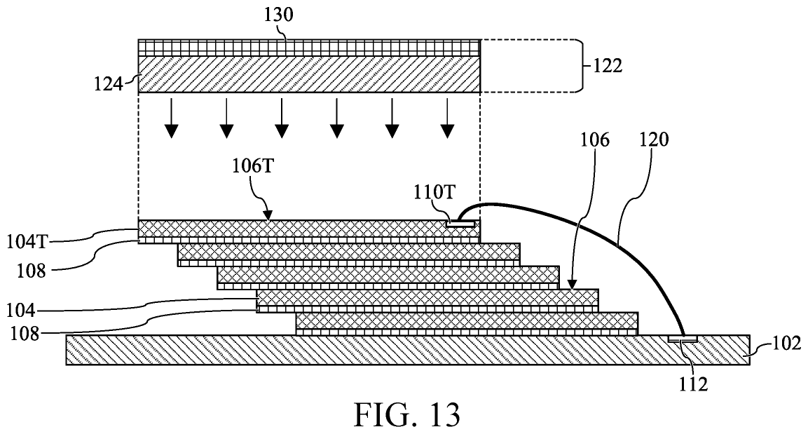

FIGS. 12-14 depict MIM structure 122 being disposed over top die 104T of the plurality of stacked dies 104, 104T. More specifically, FIGS. 12-14 show MIM structure 122 undergo various processes and preparations in order to be disposed directly over top die 104T of the plurality of stacked dies 104, 104T. Turning to FIG. 12, MIM structure 122 is position adjacent to top die 104T prior to being disposed thereover. In the non-limiting example, MIM structure 122 includes a MIM release film 140 coupled to, disposed over, and/or substantially covering adhesive layer 124 of MIM structure 122. As discussed herein, MIM release film 140 is coupled to adhesive layer 124 to protect adhesive layer 124 and/or to aid in the transportation and position of MIM structure 122. Turning to FIG. 13, MIM release film is removed from MIM structure 122 to expose adhesive layer 124. As shown, MIM structure 122 is also positioned above and/or aligned with top die 104T of the plurality of stacked dies 104, 104T. FIGS. 12 and 13 correspond to process P3 shown in FIG. 9.

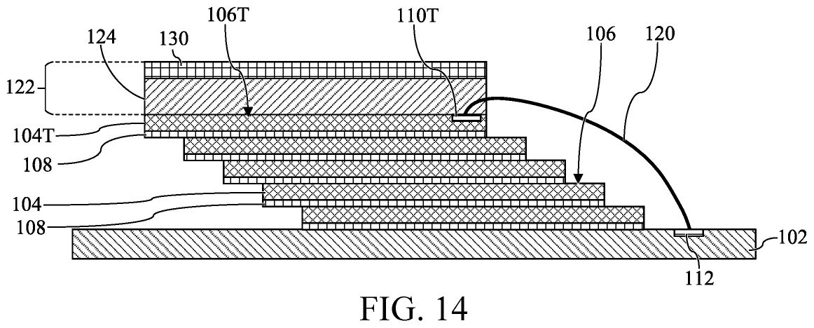

In FIG. 14, MIM structure is disposed directly over top die 104T of the plurality of stacked dies 104, 104T. More specifically, MIM structure 122 is disposed directly over and/or substantially covers top surface 106T of top die 104T. As such, no portion of top surface 106T of top die 104T is exposed and/or uncovered by MIM structure 122. Additionally, MIM structure 122 is disposed directly over and/or substantially covers die contact 110T formed in top surface 106T of top die 104T. When disposed directly over top die 104T, MIM structure 122 substantially surrounds first portion 126 of wire 120 connected to die contact 110T. The disposing of MIM structure 122 includes disposing adhesive layer 124 of MIM structure 122 directly over top surface 106T of top die 104T, where first portion 126 of wire 120 extends through and/or is substantially surrounded by adhesive layer 124. Additionally as shown, polymer layer 130 of MIM structure 122 is disposed directly over adhesive layer 124, such that adhesive layer 124 is positioned between top die 104T of the plurality of stacked dies 104, 104T and polymer layer 130. Furthermore, disposing MIM structure 122/adhesive layer 124 over top die 104T can also include curing adhesive layer 124 of MIM structure 122. Curing adhesive layer 124 of MIM structure 122 substantially hardens or firms the adhesive layer, and ultimately secures, affixes, and/or embeds first portion 126 of wire 120 within adhesive layer 124. FIG. 14 corresponds to process P4 shown in FIG. 9.

FIG. 15 shows molding compound 132 formed over substrate 102 and at least a portion of the plurality of stacked dies 104, 104T. More specifically, molding compound 132 is flowed, formed, and/or positioned over exposed portions of substrate 102 not covered by the plurality of stacked dies 104, 104T, as well as the exposed portions (e.g., top surfaces 106, sidewalls) of each die of the plurality of stacked dies 104, 104T. Molding compound 132 is also flowed over and/or substantially surrounds substrate contacts 112, and the die contacts 110 (excluding die contacts 110T formed in top surface 106T of top die 104T) formed in the stacked dies 104. Flowing molding compound 132 also includes surrounding second portion 134 of wire 120 with molding compound 132. As shown in FIG. 15, flowing molding compound 132 results in second portion 134 of wire 120 extending through, being substantially surrounded by, and/or being embedded within molding compound 132. In the non-limiting example, flowing molding compound 132 further includes forming molding compound 132 directly adjacent to: top surface 106T of top die 104T, adhesive layer 124 of MIM structure 122, and polymer layer 130 of MIM structure 122, respectively. In this example, molding compound 132 does not cover or contact top surface 106T of top die 104T, but rather surrounds top die 104T, and MIM structure 122. As such, polymer layer 130 of MIM structure 122 and 32 molding compound are in planar alignment and collectively form a top or upper surface of semiconductor package 100. FIG. 15 corresponds to process P5 shown in FIG. 9.

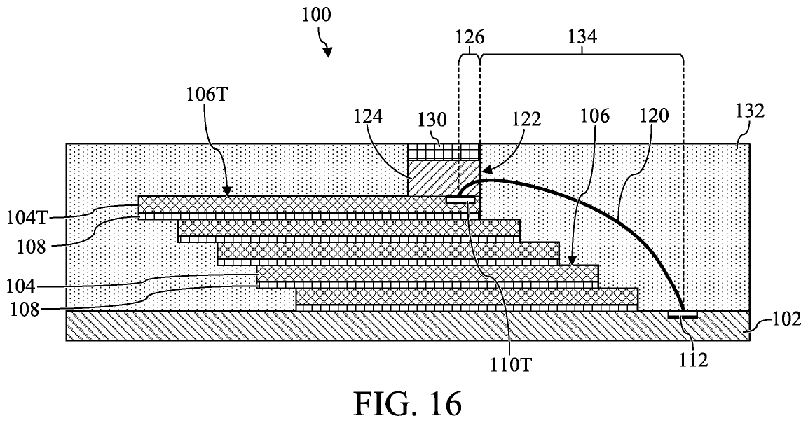

Although discussed herein as being disposed entirely over top surface 106T of top die 104T, it is understood that MIM structure 122 can be formed or disposed directly over only a portion of top surface 106T. In the non-limiting example shown in FIG. 16, MIM structure 122 is disposed directly over and/or substantially covers only a portion of top surface 106T of top die 104T including die contacts 110T. As shown, adhesive layer 124 of MIM structure 122 is disposed directly over die contracts 110T and a surrounding portion of the top surface 106T of top die 104T. Additionally, polymer layer 130 is formed or disposed over adhesive layer 124 and also is only positioned above a portion of top surface 106T of top die 104T. As similarly discussed herein, first portion 126 of wire 120 extends through, is substantially surrounded by, and/or is secured within adhesive layer 124 of MIM structure 122. In the example, the remaining portion of top surface 106T of top die 104T not covered by MIM structure 122 is substantially covered by molding compound 132. Although MIM structure 122 is only disposed over a portion of top die 104T, MIM structure 122 shown in FIG. 16 still provides semiconductor package 100 with similar benefits as those discussed herein (e.g., increased stability and/or reliability, minimizing loop height, reduced/eliminated risk of wire sweeping/sagging, etc.).

Based on the above, examples of the present disclosure describe a semiconductor package, comprising: a substrate; a plurality of stacked dies disposed over the substrate, the plurality of stacked dies including: a top die positioned above the substrate, the top die including: a top surface, and a die contact formed on the top surface; a multifunctional interface material (MIM) structure disposed over the top die, the MIM structure including: an adhesive layer disposed directly over the top surface of the top die; and a polymer layer disposed directly over the adhesive layer; and a bond wire contacting the die contact of the top die, wherein at least a portion of the bond wire extends through the adhesive layer of the MIM structure. In an example, the at least the portion of the bond wire is secured within the adhesive layer of the MIM structure. In an example, the semiconductor package also includes a molding compound disposed over the substrate and at least a portion of the plurality of stacked dies, the molding compound formed adjacent to: the top surface of the top die, and the MIM structure. In an example, the bond wire further includes another portion disposed within and extending through the molding compound. In an example, the MIM structure further includes an additive disposed within at least one of the adhesive layer or the polymer layer. In an example, the additive is disposed in the adhesive layer and the polymer layer of the MIM structure. In an example, the additive of the MIM structure includes at least one of aluminum oxide, magnesium oxide, aluminum nitride, boron nitride, or diamond powder. In an example, the adhesive layer of the MIM structure includes an epoxy resin. In an example, the adhesive layer of the MIM structure includes a height between approximately 20 micrometers (μm) to approximately 30 μm. In an example, the polymer layer of the MIM structure includes a height between approximately 10 μm to approximately 20 μm.

Examples also describe a method for creating a semiconductor package, comprising: disposing a plurality of stacked dies over a substrate, the plurality of stacked dies including: a top die positioned above the substrate, the top die including a top surface, and a die contact formed on the top surface; connecting a portion of a bond wire to the die contact of the top die; disposing a multifunctional interface material (MIM) structure directly over the top die of the plurality of stacked dies, the MIM structure surrounding the portion of the bond wire connected to the die contact of the top die; and flowing a molding compound over the substrate and at least a portion of the plurality of stacked dies. In an example, disposing the MIM structure directly over the top die of the plurality of stacked dies further includes: disposing an adhesive layer of the MIM structure directly over the top surface of the top die, the adhesive layer positioned between the top surface of the top die and a polymer layer of the MIM structure, wherein the portion of the bond wire extends through the adhesive layer; and curing the adhesive layer of the MIM structure to secure the portion of the bond wire within the adhesive layer. In an example, flowing the molding compound further includes: forming the molding compound directly adjacent to: the top surface of the top die; the adhesive layer of the MIM structure; and the polymer layer of the MIM structure. In an example, the method also includes removing a MIM release film coupled to the adhesive layer, opposite the polymer layer, prior to the disposing of the adhesive layer of the MIM structure directly over the top surface of the top die. In an example, flowing the molding compound further includes: surrounding another portion of the bond wire with the molding compound, the another portion of the bond wire formed adjacent the portion. In an example, flowing the molding compound further includes: forming the molding compound over the MIM structure.

Examples also describe an encapsulated semiconductor package, comprising: a substrate including a first contact means; a plurality of stacked dies disposed over the substrate, the plurality of stacked dies including: a top die positioned above the substrate, the top die including: a top surface, and a second contact means provided on the top surface; a connection means extending between and electrically connecting the second contact means of the top die and the first contact means of the substrate; a securing means disposed directly over the top die, the securing means receiving and securing a portion of the connection means therein; and a protective means disposed directly over the securing means. In an example, the securing means is disposed directly over the top surface and the second contact means provided on the top surface of the top die. In an example, at least one of the securing means or the protective means further includes additive means for adjusting operational characteristics of the at least one of the securing means or the protective means. In an example, the encapsulated semiconductor package also includes a distinct connection means extending between and electrically connecting a third contact means provided on the top die and a fourth contact means provided on a stacked die of the plurality of stacked dies positioned adjacent to and below the top die, wherein the securing means receives and secures a portion of the distinct connection means.

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” and/or “substantially” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A semiconductor package, comprising:
a substrate;
a plurality of stacked dies disposed over the substrate, the plurality of stacked dies including:
a top die positioned above the substrate, the top die including:
a top surface, and
a die contact formed on the top surface;
a multifunctional interface material (MIM) structure disposed over the top die, the MIM structure including:
an adhesive layer disposed directly over the top surface of the top die; and
a polymer layer disposed directly over the adhesive layer; and
a bond wire contacting the die contact of the top die, wherein at least a portion of the bond wire extends through the adhesive layer of the MIM structure.

2. The semiconductor package of claim 1, wherein the at least the portion of the bond wire is secured within the adhesive layer of the MIM structure.

3. The semiconductor package of claim 1, further comprising:
a molding compound disposed over the substrate and at least a portion of the plurality of stacked dies, the molding compound formed adjacent to:
the top surface of the top die, and
the MIM structure.

4. The semiconductor package of claim 3, wherein the bond wire further includes another portion disposed within and extending through the molding compound.

5. The semiconductor package of claim 1, wherein the MIM structure further includes an additive disposed within at least one of the adhesive layer or the polymer layer.

6. The semiconductor package of claim 5, wherein the additive is disposed in the adhesive layer and the polymer layer of the MIM structure.

7. The semiconductor package of claim 5, wherein the additive of the MIM structure includes at least one of aluminum oxide, magnesium oxide, aluminum nitride, boron nitride, or diamond powder.

8. The semiconductor package of claim 1, wherein the adhesive layer of the MIM structure includes an epoxy resin.

9. The semiconductor package of claim 1, wherein the adhesive layer of the MIM structure includes a height between approximately 20 micrometers (μm) to approximately 30 μm.

10. The semiconductor package of claim 1, wherein the polymer layer of the MIM structure includes a height between approximately 10 μm to approximately 20 μm.

11. A method for creating a semiconductor package, comprising:
disposing a plurality of stacked dies over a substrate, the plurality of stacked dies including:
a top die positioned above the substrate, the top die including a top surface, and a die contact formed on the top surface;
connecting a portion of a bond wire to the die contact of the top die;
disposing a multifunctional interface material (MIM) structure directly over the top die of the plurality of stacked dies, the MIM structure surrounding the portion of the bond wire connected to the die contact of the top die; and
flowing a molding compound over the substrate and at least a portion of the plurality of stacked dies.

12. The method of claim 11, wherein disposing the MIM structure directly over the top die of the plurality of stacked dies further includes:
disposing an adhesive layer of the MIM structure directly over the top surface of the top die, the adhesive layer positioned between the top surface of the top die and a polymer layer of the MIM structure,
wherein the portion of the bond wire extends through the adhesive layer; and
curing the adhesive layer of the MIM structure to secure the portion of the bond wire within the adhesive layer.

13. The method of claim 12, wherein flowing the molding compound further includes:
forming the molding compound directly adjacent to:
the top surface of the top die;
the adhesive layer of the MIM structure; and
the polymer layer of the MIM structure.

14. The method of claim 12, further comprising:
removing a MIM release film coupled to the adhesive layer, opposite the polymer layer, prior to the disposing of the adhesive layer of the MIM structure directly over the top surface of the top die.

15. The method of claim 11, wherein flowing the molding compound further includes:
surrounding another portion of the bond wire with the molding compound, the another portion of the bond wire formed adjacent the portion.

16. The method of claim 11, wherein flowing the molding compound further includes:
forming the molding compound over the MIM structure.

17. An encapsulated semiconductor package, comprising:
a substrate including a first contact means;
a plurality of stacked dies disposed over the substrate, the plurality of stacked dies including:
a top die positioned above the substrate, the top die including:
a top surface, and
a second contact means provided on the top surface;
a connection means extending between and electrically connecting the second contact means of the top die and the first contact means of the substrate;
a securing means disposed directly over the top die, the securing means receiving and securing a portion of the connection means therein; and
a protective means disposed directly over the securing means.

18. The encapsulated semiconductor package of claim 17, wherein the securing means is disposed directly over the top surface and the second contact means provided on the top surface of the top die.

19. The encapsulated semiconductor package of claim 17, wherein at least one of the securing means or the protective means further includes additive means for adjusting operational characteristics of the at least one of the securing means or the protective means.

20. The encapsulated semiconductor package of claim 17, further comprising:
a distinct connection means extending between and electrically connecting a third contact means provided on the top die and a fourth contact means provided on a stacked die of the plurality of stacked dies positioned adjacent to and below the top die,
wherein the securing means receives and secures a portion of the distinct connection means.
